(19) United States
(12) Patent Application Publication
(10) Pub. No.: US 2026/0006972 A1
(43) Pub. Date: Jan. 1, 2026

(54) DISPLAY FOR DISPLAYING INFORMATION

(71) Applicant: Jürgen Bremicker Beteiligungs GmbH & Co. KG, Weilheim i. OB (DE)

(72) Inventor: Herbert DOPFER, Peissenberg (DE)

(21) Appl. No.: 19/249,356

(22) Filed: Jun. 25, 2025

(30) Foreign Application Priority Data
Jun. 26, 2024 (DE) 10 2024 118 033.1

(51) Int. Cl. H10H 29/855

(52) U.S. Cl. CPC H10H 29/855

(57) ABSTRACT

A display (100) for displaying images or information, comprising a plurality of light sources (103-1, . . . , 103-n); and an optical element (105) for directing light from a first light source (103-1) in a first direction (107-1) and for directing light from a second light source (103-2) in a second direction (107-2).

The present invention relates to an electrically controlled display for displaying variable information, such as images or characters.

It is the technical task of the present invention to provide a display for displaying variable information, which can display the information in different directions as required.

This technical task is solved by subject matter according to the independent claims. Technically advantageous embodiments are the subject matter of the dependent claims, the description and the drawings.

According to a first aspect, the technical task is solved by a display for displaying variable information, comprising a plurality of light sources; and an optical element for directing light from a first light source in a first direction and for directing light from a second light source in a second direction. The light sources can be formed by individual light sources or groups of light sources. The light sources behind the optical element are spaced apart from each other. The display achieves the technical advantage that the information or image can be projected through the optical element in different directions as required, depending on the activation of the first or second light source.

In a technically advantageous embodiment of the display, the light sources are arranged in a matrix. The matrix can be a two-dimensional matrix. This achieves the technical advantage, for example, that the image or information can be displayed in a plurality of vertical and horizontal directions.

In a further technically advantageous embodiment of the display, the light sources are formed by micro LEDs or organic LEDs. This achieves the technical advantage, for example, that the light sources can be arranged close to each other and generate light efficiently.

In a further technically advantageous embodiment of the display, the display comprises a plurality of optical elements, each having a plurality of light sources. This achieves the technical advantage, for example, that the image or information can be displayed with high resolution.

In a further technically advantageous embodiment of the display, the optical elements are arranged in a matrix. The matrix can be a two-dimensional matrix. This also achieves the technical advantage, for example, that the image or information can be displayed with high resolution.

In a further technically advantageous embodiment of the display, the light sources are configured to emit light of different wavelengths. The light sources can each display a corresponding color independently of the others. This achieves the technical advantage, for example, that the display can display the image or information in color.

In a further technically advantageous embodiment of the display, the optical element comprises a converging lens, a free-form lens and/or a light guide element. This achieves the technical advantage, for example, that suitable components are used to direct the light.

In a further technically advantageous embodiment of the display, the light sources have a distance of less than 300 μm from each other. This achieves the technical advantage, for example, of a high angular resolution.

In a further technically advantageous embodiment of the display, the optical element is configured to direct light from a third light source in a third direction. This achieves the technical advantage, for example, that the image or the information can be displayed in a further direction.

In a further technically advantageous embodiment of the display, the light sources are arranged on a background plate of the display. This achieves the technical advantage, for example, that the light sources can be arranged behind the optical elements in a simple manner.

According to a second aspect, the technical task is solved by a method of displaying images or information, comprising the steps of directing light from a first light source through an optical element in a first direction; and directing light from a second light source through the optical element in a second direction. The method solves the same technical advantages as the display according to the first aspect.

Exemplary embodiments of the invention are shown in the drawings and are described in more detail below, in which:

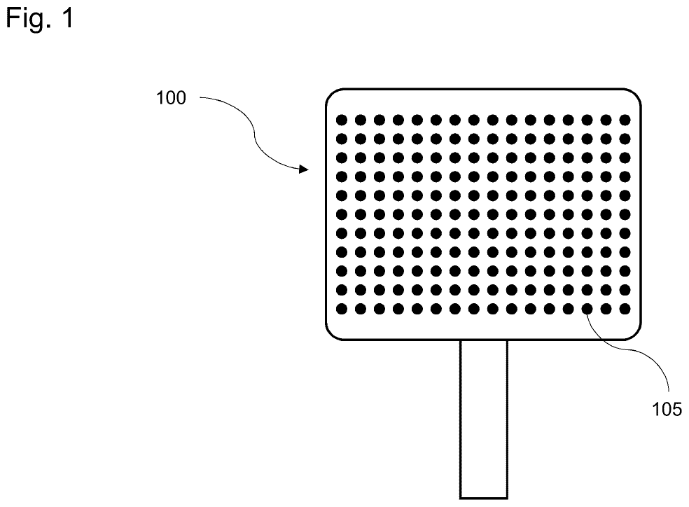

FIG. 1 shows a schematic view of a display;

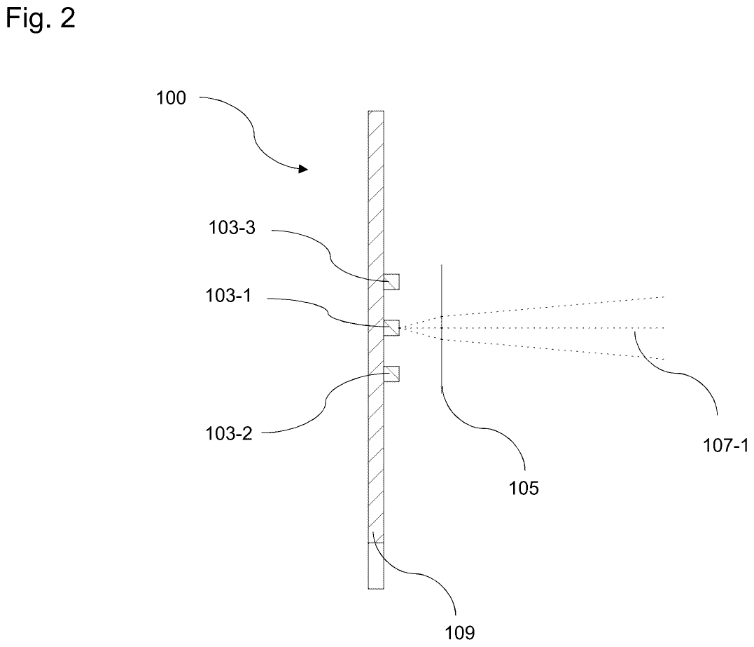

FIG. 2 shows an enlarged schematic view of the display for displaying images or information;

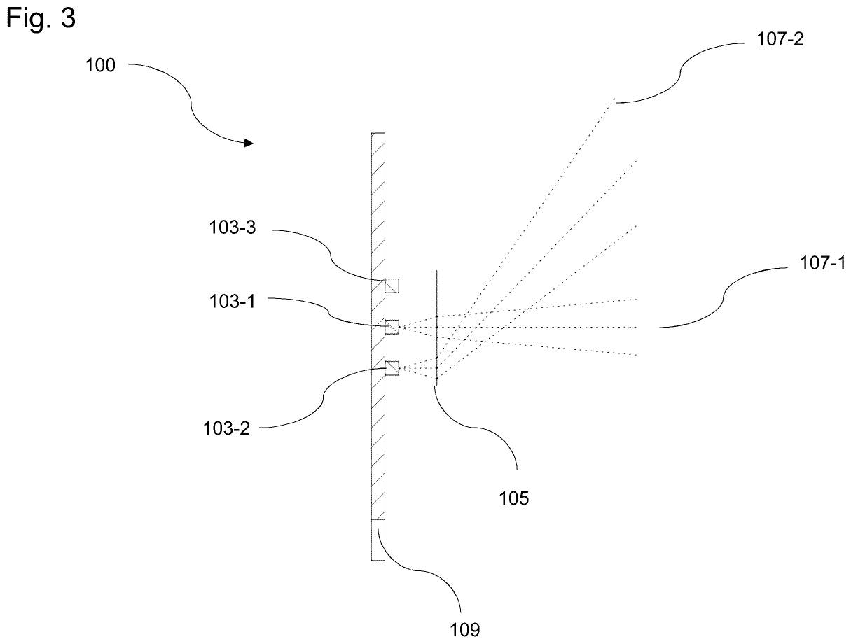

FIG. 3 shows a further enlarged schematic view of a display for displaying images or information;

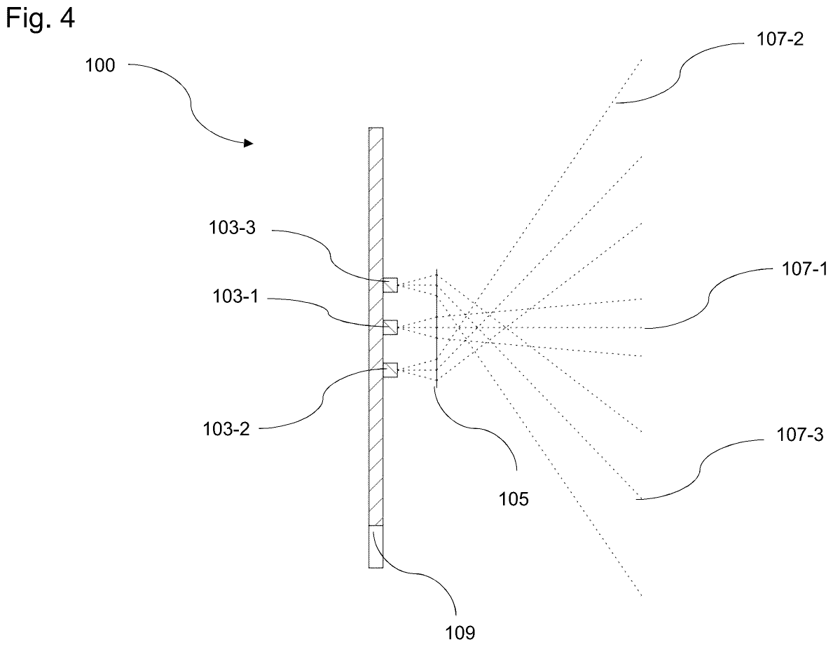

FIG. 4 shows a further enlarged schematic view of a display for displaying images or information;

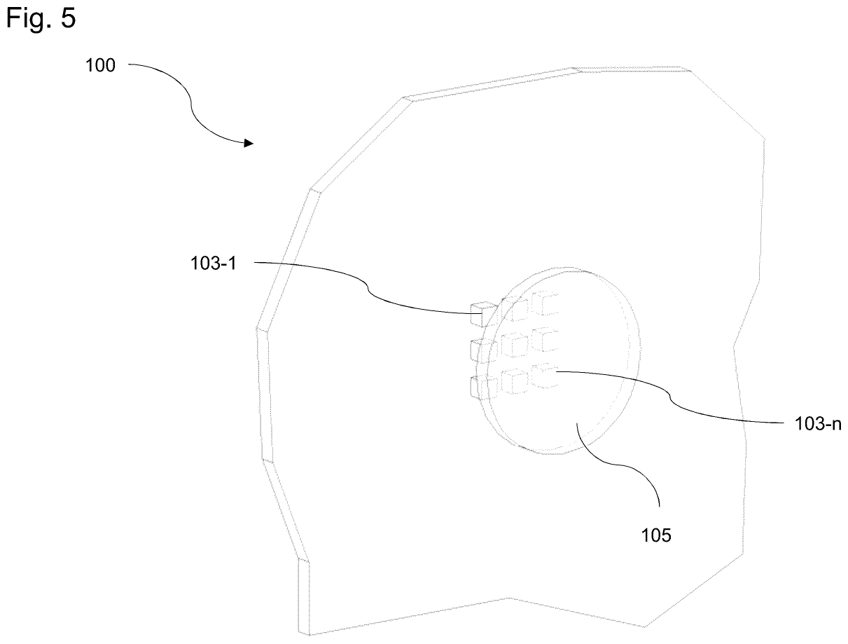

FIG. 5 shows a further enlarged schematic view of a display for displaying images or information; and

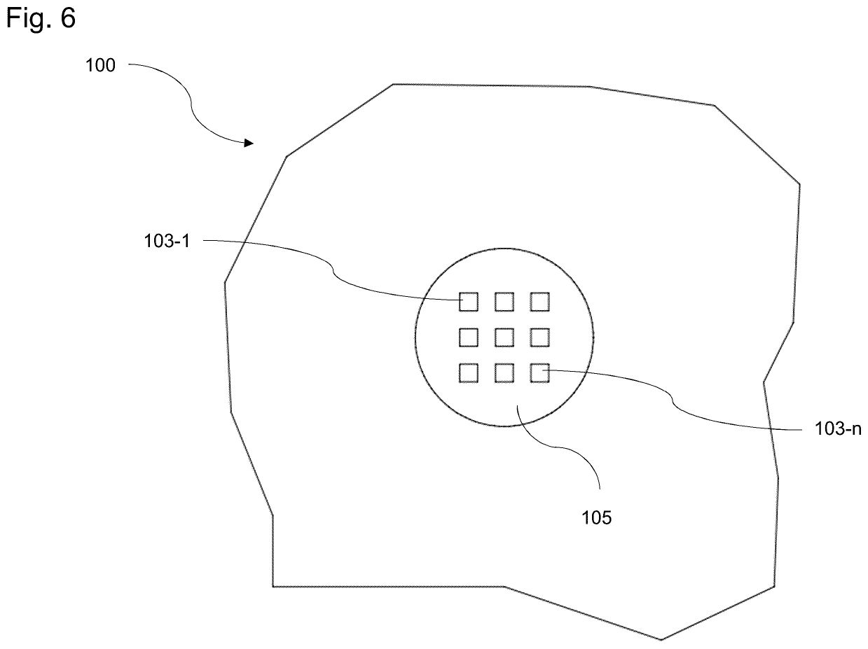

FIG. 6 shows a further enlarged schematic view of a display for displaying images or information.

FIG. 1 shows a schematic view of a display 100 for displaying images or information. The display 100 displays images or information in a way that can be visually perceived by a user. The display 100 is, for example, a monitor or a display. The display 100 can be used for a computer, as a television or within a vehicle console for displaying vehicle information. In general, however, the display 100 can also be used in a plurality of other technical environments in which images and information are to be displayed in a visually perceptible manner.

For this purpose, the display 100 comprises a plurality of transparent optical elements 105, each of which forms a luminous pixel of the displayed image. In order to display the image or the information, the display 100 comprises a matrix-shaped arrangement of these optical elements 105. By activating the respective pixels accordingly, all possible images or information can be flexibly displayed in color by the display 100. For this purpose, the display 100 comprises an electronic control unit with which the individual pixels can be controlled independently of one another in terms of color and intensity.

FIG. 2 shows an enlarged schematic view of the display 100 for displaying images or information. Each individual optical element 105 of a pixel of the display 100 is in turn assigned a plurality of spatially separated light sources 103, which are located on a flat background plate 109 behind the optical element 105. The optical element 105 bundles or collects the light from the light sources 103-1 to 103-3 and directs it in different directions depending on the position of the light source 103-1 to 103-3.

The optical element 105 is formed, for example, by a converging lens and is located, for example, at a distance from the background plate 109 with the light sources 103-1 to 103-3. Here, the optical element 105 is configured in such a way that the light of a first light source 103-1 is directed in a first direction and the light of a second light source 103-2 is directed in a second direction. In general, the number of light sources 103-1 to 103-3 that are assigned to an optical element 105 as a pixel is arbitrary. For this purpose, the optical element 105 can comprise, for example, a converging lens, a free-form lens and/or a light guide element.

The light sources 103 can be formed by individual light sources or by light source groups. The light sources 103 can, for example, each be formed by one or more light-emitting diodes. Each of the light sources 103 can be controlled independently of the other light sources. Due to the individual controllability, the light sources 103 can be activated independently of one another or their intensity and color can be changed independently of one another. By controlling the light sources 103 accordingly, the image or information can then be projected in different directions through the optical element 105.

The light sources 103 can also be formed by sections of an LED screen (MicroLED), which is arranged behind the optical element 105. Plano-convex converging lenses can be arranged on the LED screen as optical element 105.

LED screens comprise light-emitting diodes (LEDs) as self-illuminating pixels. The light-emitting diodes have, for example, a luminous width of less than 50 μm or a luminous area of less than 0.003 mm². Due to the small size of the LEDs, numerous light sources 103 can be arranged in a matrix-shaped arrangement (array) behind the optical element 105. Due to the section of an LED screen, light source groups with several light-emitting diodes can also be used as light source 103 for the optical element 105. Several sections can overlap each other.

For example, a first light source 103-1 may be formed by a first section of the LED screen and a second light source 103-2 may be formed by a second section of the LED screen. The first and second sections can overlap each other and be displayed flexibly on the LED screen. By using an LED screen as the light source 103-1 and 103-2, the intensity and color (red/green/blue) of the light source 103-1 and 103-2 can be easily controlled. In addition, light sources 103-1 and 103-2 can be generated at different positions of the LED screen so that the light can be directed in a plurality of directions. Each light-emitting diode of the LED screen can form a light source 103, which is arranged at a different position relative to the optical element 105. However, several light-emitting diodes of the LED screen may also be combined to form a single light source 103.

Since each of the individual light sources 103 can be activated independently of the other light sources 103, the image or information can be projected by the display 100 in a plurality of directions. For example, if only the light source 103-1 of the respective optical elements 105 is activated, the image or information is only displayed in one direction 107-1. This allows the image or information to be displayed exclusively for a specific user in an intended angular range. A user outside this angular range does not recognize the displayed image or information.

FIG. 3 shows a further enlarged schematic view of a display 100 for displaying images or information. In this case, the light sources 103-1 and 103-2 of the respective optical elements 105 are activated, so that the image or information is displayed simultaneously in two directions 107-1 and 107-2.

FIG. 4 shows a further enlarged schematic view of a display 100 for displaying images or information. In this case, the light sources 103-1, 103-2 and 103-3 of the respective optical elements 105 are activated, so that the image or information is displayed simultaneously in three directions 107-1, 107-2 and 107-3.

FIGS. 5 and 6 show a further schematic view of a display 100 for displaying images or information. Behind the optical element 105 there is a two-dimensional matrix-shaped arrangement of light sources 103-1, . . . , 103-n. The matrix-shaped arrangement of light sources 103-1, . . . , 103-n can be provided by an LED screen.

Depending on which light sources 103-1, . . . , 103-n are activated in the optical elements, the light can be projected in a direction assigned to the respective light sources 103-1, . . . , 103-n.

Since the light sources 103-1 to 103-n are located in a matrix-shaped arrangement behind the optical element 105, the displayed image or information can be displayed not only in different vertical directions, but also different horizontal directions or combinations of both directions.

All features explained and shown in connection with individual embodiments of the invention can be provided in different combinations in the subject matter according to the invention, in order to simultaneously realize their advantageous effects.

All method steps can be implemented by devices which are suitable for carrying out the respective method step. All functions performed by features of the subject matter can be a method step of a method.

The scope of protection of the present invention is given by the claims and is not limited by the features explained in the description or shown in the figures.

### LIST OF REFERENCES

100 Display
103 Light sources
105 Optical element
107 Direction
109 Background plate

1. A display (100) for displaying variable information, comprising:
a plurality of light sources (103-1, . . . , 103-n); and
an optical element (105) for directing light from a first light source (103-1) in a first direction (107-1) and for directing light from a second light source (103-2) in a second direction (107-2).

2. The display (100) according to claim 1, wherein the light sources (103-1, . . . , 103-n) are arranged in a matrix.

3. The display (100) according to claim 1, wherein the light sources (103-1, . . . , 103-n) are formed by micro LEDs or organic LEDs.

4. The display (100) according to claim 1, wherein the display (100) comprises a plurality of optical elements (105) each having a plurality of light sources (103-1, . . . , 103-n).

5. The display (100) according to claim 4, wherein the optical elements (105) are arranged in a matrix.

6. The display (100) according to claim 1, wherein the light sources (103-1, . . . , 103-n) are configured to emit light of different wavelengths.

7. The display (100) according to claim 1, wherein the optical element (105) comprises a converging lens, a free-form lens and/or a light guide element.

8. The display (100) according to claim 1, wherein the light sources (103-1, . . . , 103-n) have a distance of less than 300 μm from each other.

9. The display (100) according to claim 1, wherein the optical element (105) is configured to direct light from a third light source (103-3) in a third direction (107-3).

10. The display (100) according to claim 1, wherein the light sources (103-1, . . . , 103-n) are arranged on a background plate (109) of the display (100).

11. A method of displaying images or information, comprising the steps of:
directing (S101) light from a first light source (103-1) through an optical element (105) in a first direction (107-1); and
directing (S102) light from a second light source (103-2) through the optical element (105) in a second direction (107-2).
